(19) United States
(12) Patent Application Publication
(10) Pub. No.: US 2012/0025248 A1
(43) Pub. Date: Feb. 2, 2012

(54) SEMICONDUCTOR LIGHT EMITTING DEVICE AND MANUFACTURING METHOD OF THE SAME

(76) Inventor: Duk-Kyu BAE, Gyeonggi-do (KR)

(21) Appl. No.: 13/191,067

(22) Filed: Jul. 26, 2011

(30) Foreign Application Priority Data
Jul. 27, 2010 (KR) KR10-2010-0072193

(51) Int. Cl. H01L 33/38; H01L 33/44

(52) U.S. Cl. 257/98; 438/29; 257/E33.064; 257/E33.074

(57) ABSTRACT

Provided is a semiconductor light emitting device. The semiconductor light emitting device includes a conductive substrate, a p-type electrode disposed on the conductive substrate, a transparent electrode layer disposed on the p-type electrode, a light emitting structure comprising a p-type semiconductor layer, an active layer, and an n-type semiconductor layer, which are sequentially stacked on the transparent electrode layer, and an n-type electrode disposed on the n-type semiconductor layer. The light emitting structure is disposed on a top middle of the transparent electrode layer to allow a side of the light emitting structure to be spaced from an edge of the transparent electrode layer. The transparent electrode layer has an uneven surface at an outer portion of the light emitting structure.

### CROSS-REFERENCE TO RELATED APPLICATION

This application claims priority to Korean Patent Application No. 10-2010-0072193, filed on Jul. 27, 2010 and all the benefits accruing therefrom under 35 U.S.C. §119, the contents of which are incorporated by reference in their entirety.

### BACKGROUND

The present disclosure relates to a semiconductor light emitting device and a method of manufacturing the same, and more particularly, to a vertical structure semiconductor light emitting device and a method of manufacturing the same.

A semiconductor light emitting device such as a Light Emitting Diode (LED) is one of solid state electronic devices and typically includes an active layer of a semiconductor material inserted between a p-type semiconductor layer and an n-type semiconductor layer. Once drive current is applied to the both ends of the p-type semiconductor layer and the n-type semiconductor layer in the semiconductor light emitting device, electrons and holes are injected from the p- and n-type semiconductor layers to the active layer. The injected electrons and holes are recombined in the active layer to generate light.

Generally, the semiconductor light emitting device is manufactured with nitride-based III-V group semiconductor compounds having the formula AlₓIn_{y}Ga(_{1-x-y})N (0≦x≦1, 0≦y≦1, 0≦x+y≦1) and becomes a device for emitting a short wavelength light (ultraviolet light to green light), especially, a device for emitting blue light. However, since a nitride-based semiconductor compound is manufactured using a dielectric substrate such as a sapphire substrate or a silicon carbide (SiC) substrate, which satisfies a lattice matching condition, in order to apply drive current, two electrodes connected to the p- and n-type semiconductor layers have a planar structure in which the two electrodes are arranged almost horizontally on a top surface of a light emitting structure.

However, when the n- and p-type electrodes are almost horizontally arranged on a top surface of the light emitting structure, brightness is decreased due to the reduction of a light emitting area and current is not smoothly spread. Thus, reliability susceptible to ElectroStatic Discharge (ESD) becomes an issue and also the number of chips on the same wafer is reduced thereby decreasing a yield. Additionally, there are limitations in reducing a chip size and also the sapphire substrate has poor conductivity. Thus, heat generated during a high output drive is not sufficiently emitted, thereby causing limitations in device performance.

To resolve the above limitations, a laser lift off process for separating a sapphire substrate from a portion of a nitride-based semiconductor compound layer by resolving the boundary between them through the high density energy of a high output laser is used to manufacture a vertical structure semiconductor light emitting device.

FIG. 1 is a sectional view illustrating a vertical structure semiconductor light emitting device manufactured by attaching a supporting conductive substrate after separating a sapphire substrate through a laser lift off process.

Referring to FIG. 1, a related art vertical structure semiconductor light emitting device 10 includes a metal layer 35, a p-type semiconductor layer 25, an active layer 20, and an n-type semiconductor layer 15, which are sequentially disposed on a conductive substrate 40. An n-type electrode 45 is disposed on the n-type semiconductor layer 15. Once drive current is applied to both ends of the p- and n-type semiconductor layers 25 and 15, electrons and holes are injected from the p- and n-type semiconductor layers 25 and 15 to the active layer 20. The injected electrons and holes are recombined in the active layer 20 to generate light.

In a case of the vertical structure semiconductor light emitting device, it is important how high light extraction efficiency is in the same area. However, as indicated with the arrows of FIG. 1, the light generated from the related art vertical structure semiconductor light emitting device 10 has a typical light path, where light is emitted from the active layer 20, is reflected at the metal layer 35 (i.e., the interface between the p-type semiconductor layer 25 and the conductive substrate 40), and is transmitted to the outside of the n-type semiconductor layer 15 through the active layer 20 again. Since light absorption occurs when light passes through the active layer 20, light extraction efficiency is low and a light output to the external is less.

Moreover, in order to prevent a metal in the metal layer 35 from diffusing into the p-type semiconductor layer 25, as shown in FIG. 2, a semiconductor light emitting device 10′ including an anti-reflection layer 30 disposed between the interface between the p-type semiconductor layer 25 and the conductive substrate 40 and disposed on the metal layer 35 and the conductive substrate 40 is suggested. However, in this case, the anti-reflection layer 30 serves as a wave guide, so that as indicated with the arrows of FIG. 2, a light from the active layer 20 is total-reflected at the anti-reflection layer 30 and is transmitted through a side of the anti-reflection layer 30 after travelling the anti-reflection layer 30 in order to generate a light from a side of the anti-reflection layer 30. Since light travels in a substantially unwanted direction or is somewhat lost during a total reflection process, light extraction efficiency is decreased. As a result of that, light output is reduced.

### SUMMARY

The present disclosure provides a semiconductor light emitting device for preventing light output decrease when the light generated in an active layer passes through the active layer again.

The present disclosure also provides a method of manufacturing a semiconductor light emitting device for preventing light output decrease when the light generated in an active layer passes through the active layer again.

According to an exemplary embodiment, a semiconductor light emitting device including: a conductive substrate; a p-type electrode disposed on the conductive substrate; a transparent electrode layer disposed on the p-type electrode; a light emitting structure including a p-type semiconductor layer, an active layer, and an n-type semiconductor layer, which are sequentially stacked on the transparent electrode layer; and an n-type electrode disposed on the n-type semiconductor layer, wherein the light emitting structure is disposed on a top middle of the transparent electrode layer to allow a side of the light emitting structure to be spaced from an edge of the transparent electrode layer; and the transparent electrode layer has an uneven surface at an outer portion of the light emitting structure.

A thickness at an outer portion of the light emitting structure in the transparent electrode layer may be thinner than that at a lower portion of the light emitting structure in the transparent electrode layer.

The p-type electrode may have a high stepped portion at a lower portion of the light emitting structure and low stepped portions at both sides of the high stepped portion and the transparent electrode layer may be disposed on the low stepped portions.

The high stepped portion of the p-type electrode may contact the p-type semiconductor layer.

The light emitting structure may have a slant side with respect to the conductive substrate.

The light emitting structure may have a progressively narrower width toward the n-type electrode.

The semiconductor light emitting device may further include a passivation layer to cover a side of the light emitting structure.

The passivation layer may be disposed to cover an uneven portion of the transparent electrode layer.

According to another exemplary embodiment, a method of manufacturing a semiconductor light emitting device includes: forming a light emitting structure by sequentially growing an n-type semiconductor layer, an active layer, and a p-type semiconductor layer on a semiconductor substrate; forming a transparent electrode layer on the p-type semiconductor layer; forming a p-type electrode on the transparent electrode layer; attaching a conductive substrate on the p-type electrode; removing the semiconductor substrate from a result having the conductive substrate attached; removing a remaining area except a middle portion of the light emitting structure to allow a side of the light emitting structure to be spaced from an edge of the transparent electrode layer and forming an uneven outer portion surface of the light emitting structure in the transparent electrode layer; and forming an n-type electrode on the n-type semiconductor layer.

The removing of the remaining area and the forming of the uneven outer portion surface of the light emitting structure may include: removing a remaining region except a middle portion of the light emitting structure through dry etching; and forming an uneven outer portion surface of the light emitting structure in the transparent electrode layer through in-situ dry etching after the removing of the remaining region except the middle portion of the light emitting structure.

The removing of the remaining area and the forming of the uneven outer portion surface of the light emitting structure may include: removing a remaining region except a middle portion of the light emitting structure through dry etching; and forming an uneven outer portion surface of the light emitting structure in the transparent layer through wet etching.

The forming of the p-type electrode may include: forming a groove by removing a portion corresponding to a middle portion of the light emitting structure in the transparent electrode layer; and forming a metal layer on an entire surface of the transparent electrode layer having the groove.

The groove may be formed to expose the p-type semiconductor layer.

The transparent electrode layer may be formed of a transparent conductive metal oxide such as Indium Tin Oxide (ITO). The p-type electrode may be formed of a multi layer of at least one layer including one of Ag, Ni, Al, Rh, Pd, Ir, Ru, Mg, Zn, Pt, and Au.

### BRIEF DESCRIPTION OF THE DRAWINGS

Exemplary embodiments can be understood in more detail from the following description taken in conjunction with the accompanying drawings, in which:

FIGS. 1 and 2 are sectional views illustrating a related art vertical structure semiconductor light emitting device;

FIGS. 3 through 5 are sectional views illustrating a semiconductor light emitting device according to embodiments; and

FIGS. 6 and 7 are manufacturing sectional views illustrating a method of manufacturing a semiconductor light emitting device according to embodiments.

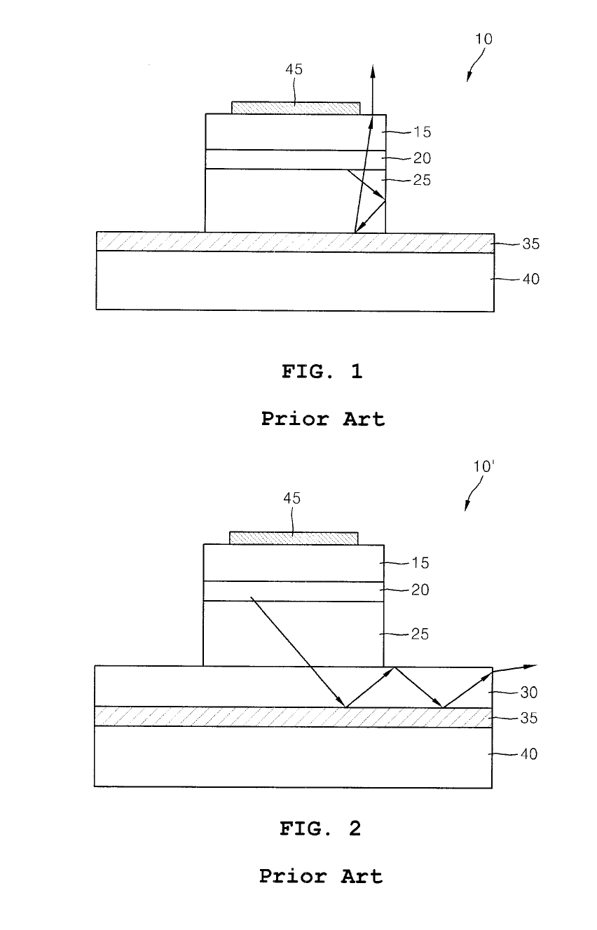

### DETAILED DESCRIPTION OF EMBODIMENTS

Hereinafter, specific embodiments will be described in detail with reference to the accompanying drawings. However, the invention may be embodied in many different forms and should not be construed as being limited to the embodiments set forth herein; rather, these embodiments are provided so that this disclosure will be thorough and complete, and will fully convey the concept of the invention to those skilled in the art. In the drawings, the thicknesses of layers and regions are exaggerated for clarity.

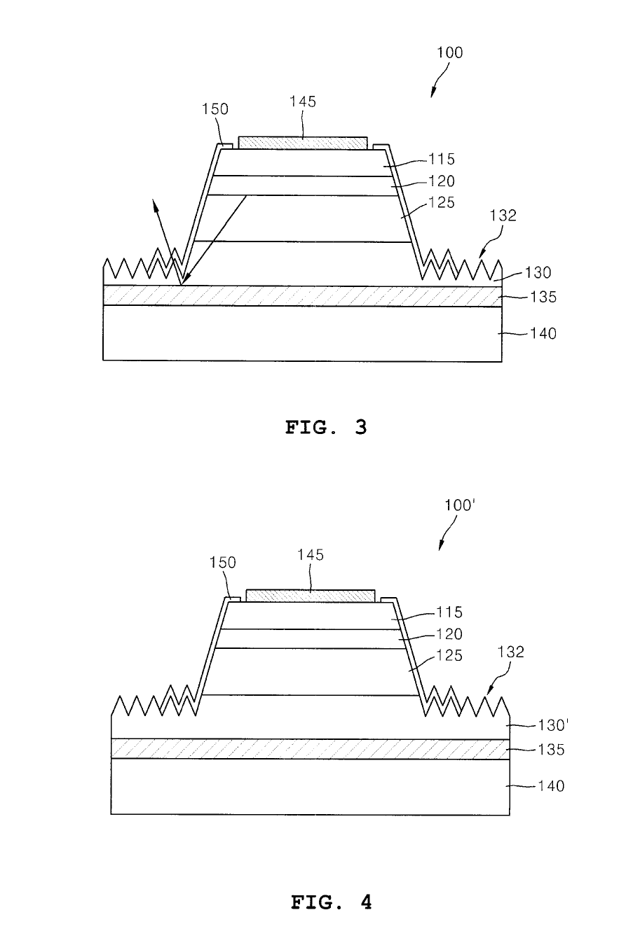

FIG. 3 is a sectional view illustrating a semiconductor light emitting device according to an embodiment.

Referring to FIG. 3, the semiconductor light emitting device 100 includes a conductive substrate 140, and a p-type electrode 135, a transparent electrode layer 130, a p-type semiconductor layer 125, an active layer 120, an n-type semiconductor layer 115, and an n-type electrode 145, which are sequentially disposed on the conductive substrate 140. The p-type semiconductor layer 125, the active layer 120, and the n-type semiconductor layer 115, which are sequentially stacked on the transparent electrode layer 130, constitute a light emitting structure. This light emitting structure is disposed on the top middle portion of the transparent electrode layer 130 in order for the sides of the light emitting structure to be spaced from the edges of the transparent electrode layer 130.

An outer portion of the light emitting structure in the transparent electrode layer 130 has an uneven surface 132. The uneven surface 132 may have a pyramid shape or a shape similar thereto. The transparent electrode layer 130 may serve to prevent the light generated from the active layer 120 from being incident to the active layer 120 again after reflection. Additionally, when heat is applied during a following process, the transparent electrode layer 130 may effectively prevent metal elements of the p-type electrode 135 from transferring through diffusion, thereby reduce leakage current. When considering these, the transparent electrode layer 130 may be formed of a transparent conductive metal oxide such as Indium Tin Oxide (ITO).

As indicated with the arrows of FIG. 3, the light from the active layer 120 is induced into the transparent electrode layer 130 but is easily emitted to the external after contacting the uneven surface 132. Accordingly, this prevents the light generated in the active layer 120 from being reflected to the active layer 120 again without a side effect of typical lateral light occurrence. Accordingly, there is no light absorption in the active layer 120 so that light output to the external is not reduced.

The light emitting structure may be formed with a slant side with respect to the conductive substrate 140. At this point, as shown in the drawing, the light emitting structure may have a progressively narrower width toward the n-type electrode 145. Thus, the slant side structure may have a broad light emitting area.

The semiconductor light emitting device 100 may further include a passivation layer 150 to cover the side of the light emitting structure. The passivation layer 150 is formed of an insulating dielectric for side protection such as electrical insulation and impurity penetration prevention. At this point, the passivation layer 150 may cover the uneven surface 132 of the transparent electrode layer 130 and, as shown in FIG. 3, may cover a portion of the uneven surface 132 or an entire surface of the transparent electrode layer 130. The passivation layer 150 may be omitted to adjust a radiation angle or minimize light absorption.

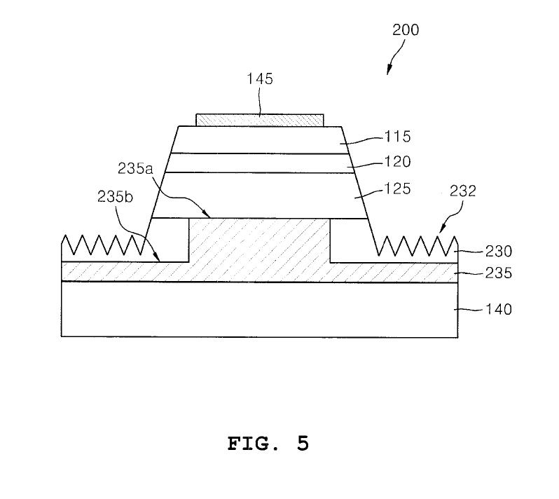

The transparent electrode layer 130 has a thickness at a bulging portion in the uneven surface 132 of the transparent electrode layer 130, which is thinner than that at lower portion of the light emitting structure as shown in FIG. 3. That is, the thickness at the outer portion of the light emitting structure is thinner than that at the lower portion of the light emitting structure in the transparent electrode layer 130. These thicknesses may vary. For example, referring to FIG. 4 according to a modification of the embodiment, the thickness of a transparent electrode layer 130′ at a bulging portion in the uneven surface 132 of the transparent electrode layer 130′ is identical to that of the transparent electrode layer 130′ at the lower portion of the light emitting structure.

FIG. 5 is a sectional view of a semiconductor light emitting device according to an embodiment. Like reference refer to like elements throughout and overlapping description will be omitted.

The semiconductor light emitting device 200 of FIG. 5 is identical to the semiconductor light emitting device 100 of FIG. 3 except the transparent electrode layer 230 and the p-type electrode 235. In FIG. 5, the passivation layer 150 of FIG. 3 is omitted. An uneven surface 232 is formed at an outer portion of the light emitting structure in the transparent electrode layer 230.

The p-type electrode 235 may have a high stepped portion 235a at the lower portion of the light emitting structure and low stepped portions 235b at both sides of the high stepped portion 235a. The transparent electrode layer 230 may be disposed on the low stepped portions 235b. Especially, the high stepped portion 235a of the p-type electrode 235 contacts the p-type semiconductor layer 125. The shapes of the transparent electrode layer 230 and the p-type electrode 235 may be applicable to the modification of the embodiment shown in FIG. 4.

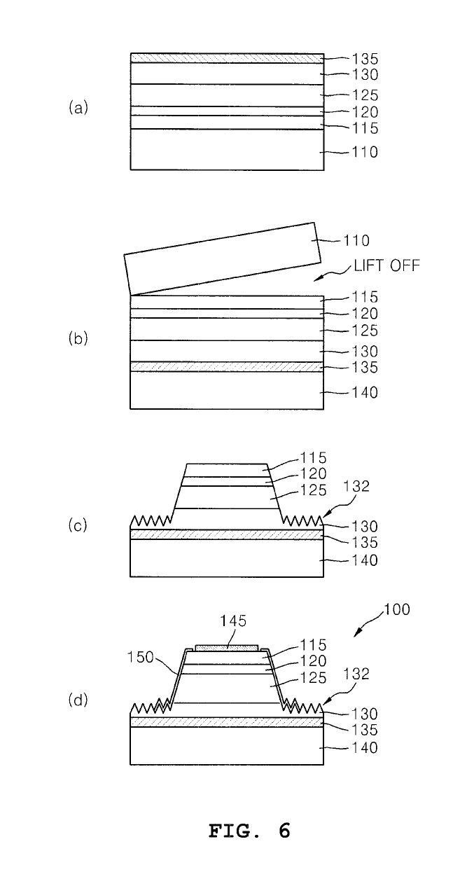

FIG. 6 is a manufacturing sectional view illustrating a method of manufacturing a semiconductor light emitting device according to an embodiment. Here, according to a method of manufacturing a typical vertical structure nitride-based III-V group semiconductor compound semiconductor light emitting device, a plurality of light emitting devices are manufactured using a predetermined wafer, but for convenience of description, the method of manufacturing only one light emitting device is shown in FIG. 6 according to this embodiment.

First, as shown in FIG. 6(a), after a light emitting structure is formed by sequentially growing an n-type semiconductor layer 115, an active layer 120, and a p-type semiconductor layer 125 on a semiconductor substrate 110, a transparent electrode layer 130 is formed on the p-type semiconductor layer 125. Then, a p-type electrode 135 is formed on the transparent electrode layer 130.

The semiconductor substrate 110 may be a proper substrate to grow a nitride semiconductor single crystal and may be formed of SiC, ZnO, GaN, or AlN besides sapphire.

Before the n-type semiconductor layer 115 grows, a buffer layer (not shown) for improving lattice matching with the semiconductor substrate 110 may be formed of AlN/GaN. The n-type semiconductor layer 115, the active layer 120, and the p-type semiconductor layer 125 may be formed of a semiconductor material having the formula In_{X}Al_{Y}Ga_{1-X-Y}N (0≦X, 0≦Y, X+Y≦1). In more detail, the n-type semiconductor layer 115 may be formed of a GaN layer or a GaN/AlGaN layer doped with an n-type impurity and the n-type impurity includes Si, Ge, Sn, Te or C but Si may be especially used for the n-type impurity. Moreover, the p-type semiconductor layer 125 may be formed of a GaN layer or a GaN/AlGaN layer doped with a p-type impurity and the p-type impurity includes Mg, Zn, and Be but Mg may be especially used for the p-type impurity. Furthermore, the active layer 120 generates and emits light and is formed with a multi-quantum well in which an InGAN layer is typically used as a well and a GaN layer is typically used as a wall layer. The active layer 120 may include one quantum well layer or a double hetero structure. The buffer layer, the n-type semiconductor layer 115, the active layer 120, and the p-type semiconductor layer 125 may be formed through a deposition process such as Metal-Organic Chemical Vapor Deposition (MOCVD), Molecular Beam Epitaxy (MBE), or Hydride Vapor Phase Epitaxy (HVPE).

The transparent electrode layer 130 prevents the light generated from the active layer 120 from being reflected to the active layer 120 again and prevents metal elements in the p-type electrode 135 from being diffused, as mentioned above. As mentioned later, the transparent electrode layer 130 may be used for detecting an etching end point when the light emitting structure is dry-etched. A transparent conductive metal oxide such as Indium Tin Oxide (ITO) satisfies all the above functions. In this case, the transparent electrode layer 130 may be formed through well known methods such as sputtering and a deposition process.

The p-type electrode 135 may serve as an ohmic contact with respect to the conductive substrate 140, serve to reflect the light generated from the active layer 120, and serve as an electrode. The p-type electrode 135 may be formed of a multi layer of at least one layer including one of Ag, Ni, Al, Rh, Pd, Ir, Ru, Mg, Zn, Pt, and Au. In consideration of reflection, the p-type electrode 135 may be formed of combined layers such as Ni/Ag, Zn/Ag, Ni/Al, Zn/Al, Pd/Ag, Pd/Al, Ir/Ag, Ir/Au, Pt/Ag, Pt/Al, and Ni/Ag/Pt layers.

Next, as shown in FIG. 6(b), a conductive substrate 140 is attached to the p-type electrode 135. The conductive substrate 140 may serve as a supporter for supporting the light emitting structure, as a component in the final semiconductor light emitting device 100. Especially, when the semiconductor substrate 110 is removed through a laser lift off process or a chemical lift off process, described later, the conductive substrate 140 is attached to the p-type electrode 135, so that a light emitting structure having a relatively thin thickness may be more easily treated.

The conductive substrate 140 may be formed of one selected from Si, Cu, Ni, Au, W and Ti and, according to the selected one, may be directly formed on the p-type electrode 135 through a process such as plating, deposition, and sputtering. Here, as an embodiment, the conductive substrate 140 is attached through a wafer bonding process, but the present invention is not limited thereto. A bonding metal layer formed of a eutectic alloy including Au and Sn as main components may be further deposited on the p-type electrode 135 and the conductive substrate 140 may be attached using the bonding metal layer as a medium through a pressurizing/heating method.

Then, the semiconductor substrate 110 is removed. At this point, a laser lift off process or a chemical lift off process may be used. For example, when the laser lift off process is used, a laser beam is projected on an entire surface of the semiconductor substrate 110 to separate the semiconductor substrate 110. When the chemical lift off process is used, after a sacrificial layer, which may be removed through wet etching, is further provided between the semiconductor substrate 110 and the light emitting structure, the semiconductor substrate 110 is separated using an etchant, which may selectively remove the sacrificial layer. Due to the lift off process, the n-type semiconductor layer 115 (or a buffer layer if any) contacting the semiconductor substrate 110 may have an exposed surface. When the surface exposed when the semiconductor substrate 110 is removed may be processed with wet cleaning solution or plasma, so that a process for removing impurities that occur during the lift off process may be further included.

Next, as shown in FIG. 6(c), a remaining area except the middle portion of the light emitting structure is removed in order for the side of the light emitting structure to be spaced from the edge of the transparent electrode layer 130. At this point, wet etching may be used but, in this embodiment, dry etching such as Inductively Coupled Plasma-Reactive Ion Etching (ICP-RIE) is used. Through the dry etching process, the n-type semiconductor layer 115, the active layer 120, and the p-type semiconductor layer 125 are etched, and the transparent electrode layer 130 may not be etched to be used to detect an etching end point. Accordingly, a combination of etching gases with selectivity is used.

While a remaining area except the middle portion of the light emitting structure is removed in order for the side of the light emitting structure to be spaced from the edge of the transparent electrode layer 130, an uneven surface 132 is formed on the outer portion surface of the light emitting structure in the transparent electrode layer 130. The uneven surface 132 may be formed by further performing dry etching in-situ with a changed kind of etching gas after etching is completed on the light emitting structure. Even if an etching gas type is not changed, the uneven surface 132 is formed by increasing plasma intensity or lengthening etching time. If dry etching is used, an uneven structure for light extraction with uniform density and desired size may be formed. The etching depth for forming the uneven surface 132 may be adjusted through an etching gas type, plasma intensity, and etching time, especially may be easily adjusted through etching time.

Wet etching may be used for forming the uneven surface 132. The uneven surface may be formed on the outer portion surface of the light emitting structure in the transparent electrode layer 130 if an etchant such as a Buffered Oxide Etchant (BOE) is used. The etching depth for forming the uneven surface 132 may be adjusted through molar concentration, etching temperature, and etching time of an etchant, especially, may be easily adjusted through etching time. If wet etching is used, compared to the dry etching, damage may less occur on the surface of the transparent electrode layer 130.

Next, as shown in FIG. 6(d), an n-type electrode 145 is formed on the n-type semiconductor layer 115. Before that, the n-type semiconductor layer 115 may have a rough surface using an alkaline solution to improve light extraction and a potion where the n-type electrode 145 is to be deposited may be protected using a mask. After the forming of the n-type electrode 145, a passivation layer 150 is formed using a dielectric to protect the side of the n-type electrode 145. Of course, after the passivation layer 150 is formed, the n-type electrode 145 may be formed.

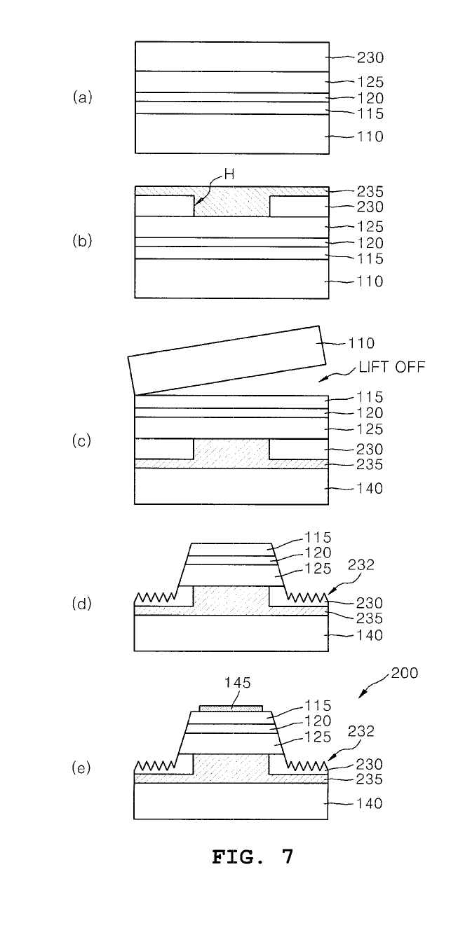

FIG. 7 is a manufacturing sectional view illustrating a method of manufacturing a semiconductor light emitting device according to another embodiment. Here, for convenience of description, a method of manufacturing one light emitting device is shown. Overlapping description will be omitted for conciseness.

As shown in FIG. 7(a), a process for sequentially forming an n-type semiconductor layer 115 to a transparent electrode layer 230 on a semiconductor substrate 110 is identical to that of FIG. 6(a).

Next, referring to FIG. 7(b), a groove H is formed by removing a portion corresponding to the middle portion of a light emitting structure in a transparent electrode layer 230. The groove H may be formed to expose a p-type semiconductor layer 125. Then, a metal layer is formed on an entire surface of the transparent electrode layer 230 including the groove H to form a p-type electrode 235. At this point, the forming of the p-type electrode 235 may be divided into two operations. First, after a reflective metal is formed to fill the region of the groove H, a metal for ohmic contact may be formed on the surface of the reflective metal and the transparent electrode layer 230.

Next, as shown in FIG. 7(c), a conductive substrate 140 is attached on the p-type electrode 235 and the semiconductor substrate 110 is removed. Then, as shown in FIG. 7(d), a remaining area except the middle portion of the light emitting structure is removed in order for the side of the light emitting structure to be spaced from the edge of the transparent electrode layer 230. Additionally, an uneven surface 232 is formed on the outer portion surface of the light emitting structure in the transparent electrode layer 230. Then, as shown in FIG. 7(e), an n-type electrode 145 is formed on the n-type semiconductor layer 115.

According to the embodiments, since the transparent electrode layer with an uneven surface is included on the outer surface of the light emitting structure at an interface between the p-type semiconductor layer and the conductive substrate, the light generated in an active surface is prevented from being reflected to the active layer again. The light from the active layer is induced into the transparent electrode layer but is not wave-guided and contacts the uneven surface to be easily emitted to the external. Accordingly, a typical side effect of lateral light occurrence can be removed. Therefore, there is no light absorption in the active layer so that a light output to the external is not reduced.

Although the semiconductor light emitting device and the method of manufacturing the same have been described with reference to the specific embodiments, they are not limited thereto. Therefore, it will be readily understood by those skilled in the art that various modifications and changes can be made thereto without departing from the spirit and scope of the present invention defined by the appended claims.

What is claimed is:

1. A semiconductor light emitting device comprising:
a conductive substrate;
a p-type electrode disposed on the conductive substrate;
a transparent electrode layer disposed on the p-type electrode;
a light emitting structure comprising a p-type semiconductor layer, an active layer, and an n-type semiconductor layer, which are sequentially stacked on the transparent electrode layer; and
an n-type electrode disposed on the n-type semiconductor layer,
wherein the light emitting structure is disposed on a top middle of the transparent electrode layer to allow a side of the light emitting structure to be spaced from an edge of the transparent electrode layer; and
the transparent electrode layer has an uneven surface at an outer portion of the light emitting structure.

2. The semiconductor light emitting device of claim 1, wherein a thickness at an outer portion of the light emitting structure in the transparent electrode layer is thinner than that at a lower portion of the light emitting structure in the transparent electrode layer.

3. The semiconductor light emitting device of claim 1, wherein the p-type electrode has a high stepped portion at a lower portion of the light emitting structure and low stepped portions at both sides of the high stepped portion and the transparent electrode layer is disposed on the low stepped portions.

4. The semiconductor light emitting device of claim 3, wherein the high stepped portion of the p-type electrode contacts the p-type semiconductor layer.

5. The semiconductor light emitting device of claim 1, wherein the light emitting structure has a slant side with respect to the conductive substrate.

6. The semiconductor light emitting device of claim 5, wherein the light emitting structure has a progressively narrower width toward the n-type electrode.

7. The semiconductor light emitting device of claim 1, further comprising a passivation layer to cover a side of the light emitting structure.

8. The semiconductor light emitting device of claim 7, wherein the passivation layer is disposed to cover an uneven portion of the transparent electrode layer.

9. A method of manufacturing a semiconductor light emitting device, the method comprising:
forming a light emitting structure by sequentially growing an n-type semiconductor layer, an active layer, and a p-type semiconductor layer on a semiconductor substrate;
forming a transparent electrode layer on the p-type semiconductor layer;
forming a p-type electrode on the transparent electrode layer;
attaching a conductive substrate on the p-type electrode;
removing the semiconductor substrate from a result having the conductive substrate attached;
removing a remaining area except a middle portion of the light emitting structure to allow a side of the light emitting structure to be spaced from an edge of the transparent electrode layer and forming an uneven outer portion surface of the light emitting structure in the transparent electrode layer; and
forming an n-type electrode on the n-type semiconductor layer.

10. The method of claim 9, wherein the removing of the remaining area and the forming of the uneven outer portion surface of the light emitting structure comprise:
removing a remaining region except a middle portion of the light emitting structure through dry etching; and
forming an uneven outer portion surface of the light emitting structure in the transparent electrode layer through in-situ dry etching after the removing of the remaining region except the middle portion of the light emitting structure.

11. The method of claim 9, wherein the removing of the remaining area and the forming of the uneven outer portion surface of the light emitting structure comprise:
removing a remaining region except a middle portion of the light emitting structure through dry etching; and
forming an uneven outer portion surface of the light emitting structure in the transparent layer through wet etching.

12. The method of claim 9, wherein the forming of the p-type electrode comprises:
forming a groove by removing a portion corresponding to a middle portion of the light emitting structure in the transparent electrode layer; and
forming a metal layer on an entire surface of the transparent electrode layer having the groove.

13. The method of claim 12, wherein the groove is formed to expose the p-type semiconductor layer.
